(19) United States
(12) Patent Application Publication
(10) Pub. No.: US 2019/0337119 A1
(43) Pub. Date: Nov. 7, 2019

(54) PAD CONDITIONER WITH SPACER AND WAFER PLANARIZATION SYSTEM

(71) Applicant: 3M INNOVATIVE PROPERTIES COMPANY, St. Paul, MN (US)

(72) Inventors: I-Hsiang Lin, New Taipei City (TW); Po Cheng To, New Taipei City (TW); Noah O. Shanti, Maplewood, MN (US)

(21) Appl. No.: 16/470,571

(22) PCT Filed: Dec. 18, 2017
(86) PCT No.: PCT/IB2017/058053

§ 371 Date: Jun. 18, 2019

Related U.S. Application Data
(60) Provisional application No. 62/437,144, filed on Dec. 21, 2016.

(51) Int. Cl. B24B 53/017; B24B 37/24; B24B 37/26; B24D 18/00; H01L 21/321; H01L 21/67

(52) U.S. Cl. CPC B24B 53/017; B24B 37/245; H01L 21/67092; B24D 18/0009; H01L 21/3212; B24B 37/26

(57) ABSTRACT

A pad conditioner includes a carrier, at least one abrasive element, and a spacer. The carrier includes a surface with an exposed region and a plurality of mounting regions. The abrasive element is disposed on the mounting region of the carrier, and at least one abrasive element has a working surface including a plurality of features each having a distal end. The spacer is disposed on the surface of the carrier and covers at least a portion of the exposed region. The spacer has a first surface and a second surface, wherein the second surface is opposed to the first surface and adjacent to the surface of the carrier. The distance D1 between the distal end of the highest feature of the at least one abrasive element and the surface of the carrier is greater than the distance D2 between the first surface of the spacer and the surface of the carrier.

### FIELD OF THE INVENTION

The present invention relates to a spacer of a pad conditioner for wafer chemical mechanical planarization system, the pad conditioner with such spacer and the wafer chemical mechanical planarization system having a pad conditioner with such spacer.

### BACKGROUND OF THE INVENTION

Chemical mechanical planarization (CMP) is a process for smoothing wafer surfaces. To provide a proper abrasive capability, the surface of the pad is refreshed by pad conditioner sweeping over the pad surface between the pad center and the edge of the pad.

Diamond disk pad conditioner is commonly used in CMP process. However, if the diamond grits of the diamond disks are not uniformly embedded, wafer damage will be caused during the CMP operation. To fix such problem, a new type of chemical vapor deposition (CVD) pad conditioner was developed (US publication US20150209932A1 (Duy K Lehuu et. al.), US20150087212A1 (Patrick Doering et. al.), US20160074993A1 (Joseph Smith et. al.), US20160121454A1 (Jun Ho Song et. el.), US20090224370A1 (David E. Slutz), US 20110250826A1 (So Young Yoon et. al.), and U.S. Pat. No. 5,921,856A (Jerry W. Zimmer)).

### SUMMARY OF THE INVENTION

Comparing with diamond disk pad conditioner, the CVD pad conditioner shows several advantages such as long disk lifetime, low wafer defect rate, low pad wear rate and high disk consistency. But the sweep distance on pad surface of the new type of pad conditioner is less than the diamond disk pad conditioner. In other words, sweep distance of the new type of pad conditioner is restricted to the abrasive element numbers and positions.

To solve the problems, the current invention is to provide a spacer for the CVD pad conditioner applied in chemical mechanical planarization process. With the pad conditioner of the current invention, the pad edge damage (such as roll up) when the pad conditioner spins over the edge of the pad can be avoided. Also, the creation of greater depth of penetration and friction near the pad edge caused by the increase of downforce for the elements remaining on the pad due to portions of the pad conditioner sweeping beyond the pad diameter can be mitigated.

In one embodiment, the present invention is a pad conditioner including a carrier, at least one abrasive element, and a spacer. The carrier includes a surface with an exposed region and a plurality of mounting regions. The abrasive element is disposed on the mounting region of the surface of the carrier, and at least one abrasive element having a working surface includes a plurality of features each having a distal end. The spacer is disposed on the surface of the carrier and covering at least a portion of the exposed region, wherein the spacer has a first surface and a second surface opposed to the first surface, and the second surface is adjacent to the surface of the carrier. The distance (D1) between the distal end of the highest feature of the at least one abrasive element and the surface of the carrier is greater than the distance (D2) between the first surface of the spacer and the surface of the carrier.

In another embodiment, the present invention is a spacer being disposed on a pad conditioner which includes a carrier and at least an abrasive element. The carrier of the pad conditioner comprises a surface with plural mounting regions and an exposed region. The abrasive element is disposed on the mounting region of the surface of the carrier and comprises a plurality of features. The spacer includes a first surface and a second surface opposed to each other, wherein the second surface is adjacent to the carrier. The distance (D1) between the distal end of the highest feature of the abrasive element and the surface of the carrier is greater than the distance (D2) between the first surface of the spacer and the surface of the carrier.

In yet another embodiment, the present invention is a wafer chemical mechanical planarization system includes a platen, a pad disposed on the platen and having an abrasive face, and a pad conditioner. The pad conditioner includes a carrier, at least one abrasive element, and a spacer. The carrier includes a surface with an exposed region and plurality of mounting regions, and the abrasive element is disposed on the mounting region of the surface of the carrier. At least one abrasive element includes a working surface facing the pad and including a plurality of features each having a distal end. The spacer is disposed on the surface of the carrier and covering at least a portion of the exposed region, wherein the spacer has a first surface and a second surface opposed to each other, and the second surface is adjacent to the carrier surface. The distal end of the highest feature of the abrasive element is in contact with the abrasive face of the pad, and the first surface of the spacer and the abrasive face of the pad have a gap (G) therebetween.

### BRIEF DESCRIPTION OF THE DRAWING

FIG. 1 is a schematic diagram of the pad conditioner according to one embodiment of the present invention.

FIG. 2 is the a-a′ cross-sectional view of FIG. 1.

FIG. 3 is the enlarged view for zone b in FIG. 2.

FIG. 4 is a schematic diagram of the wafer chemical mechanical planarization system according to one embodiment of the present invention.

FIG. 5 is a top view of the pad conditioner according to a second embodiment of the present invention.

FIG. 6 is a top view of the pad conditioner according to a third embodiment of the present invention.

FIG. 7 is a top view of the pad conditioner according to a fourth embodiment of the present invention.

FIG. 8 is a top view of the pad conditioner according to a fifth embodiment of the present invention.

FIG. 9 is a top view of the pad conditioner according to a sixth embodiment of the present invention.

FIG. 10 is a top view of the pad conditioner according to a seventh embodiment of the present invention.

FIGS. 11(a)-(h) are the tilt degree of the disk at different positions for Comparison Example 1.

FIG. 12(a)-(h) are the tilt degree of the disk at different positions for Example 1.

FIG. 13 is the comparison of the tilt degree for Comparison Example 1 and Example 1.

### DETAILED DESCRIPTION OF THE INVENTION

The embodiments of the present invention will be described in detail with the accompanying set of drawings. However, the present invention shall not be limited by the drawings and may be embodied in other forms. The same reference numerals are used to indicate the same or similar elements throughout the descriptions hereinafter.

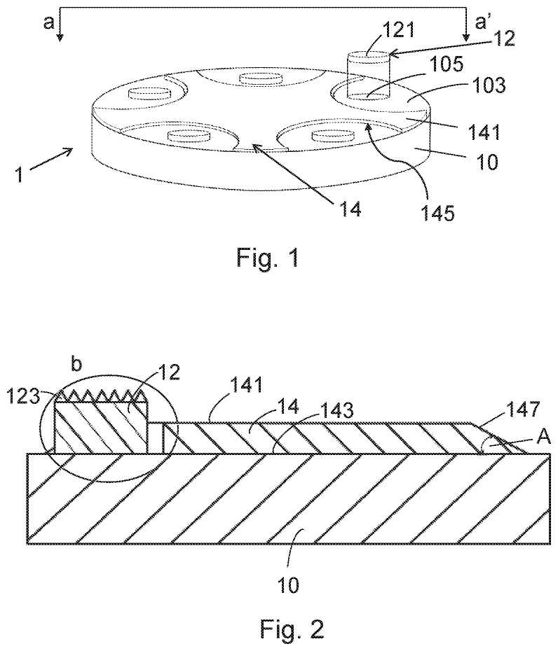

Referring now to FIG. 1, the pad conditioner 1 for chemical mechanical planarization (CMP) process includes a carrier 10, at least one abrasive element 12 and a spacer 14. The carrier 10 comprises a surface 101 including an exposed region 103 and plural mounting regions 105. In this embodiment, the carrier 10 is a circular shape, and the mounting regions 105 are spaced apart in an equal interval around the circumference of the carrier 10.

The abrasive elements 12 are disposed on the mounting regions 103 of the surface 101 of the carrier 10 via adhesives, but the method for fixing the abrasive elements 12 to the mounting regions 103 of the carrier 10 is not limited. The abrasive elements 12 are spaced apart in an equal interval around the circumference of the carrier 10. In this embodiment, there are 5 abrasive elements mounting on the carrier 10, and thus the abrasive elements 12 are spaced apart equally 72 degrees around the circumference of the carrier 10. However, the number of the abrasive elements 12 is not limited, which can be adjusted according to different requirement. Other embodiments may comprise as few as one or as many as 16 abrasive elements.

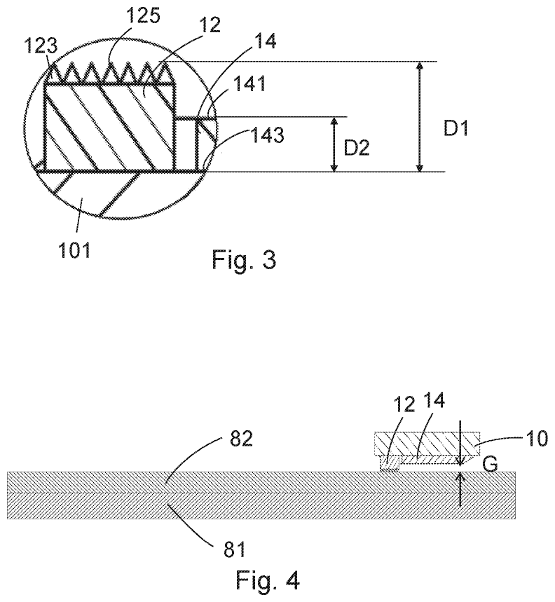

At least one of the abrasive elements 12 comprises a working surface 121 with plural features 123 formed thereon. In this embodiment, each of the abrasive elements 12 has plural features 123 forming on the working surface 121 (FIGS. 2 and 3). Each of the features 123 has a distal end 125, and the distal end 125 of the highest feature 123 of the abrasive element 12 and the surface 101 of the carrier 10 have a distance D1 therebetween. The features 123 are precisely shaped features which can be formed from methods such as machining or micromachining, water jet cutting, injection molding, extrusion, microreplication or ceramic die pressing. However, the shape of the features 123 is not limited to precisely shape, and the shape of the features can be modified according to different abrasive requirement. In some embodiments of the invention, the abrasive elements 12 may comprise the following: a superabrasive grit in a metal matrix, ceramic bodies comprising ceramic material in an amount of at least 85% by weight, and ceramic bodies comprising a diamond coating. Examples of superabrasive grit are cubic boron nitride (CBN) and CVD diamond. The details of the carrier 10 and abrasive elements 12 are discussed in US patent publication US20150209932 A1 (Duy K. Lehuu, et. al), which is herein incorporated by reference.

In addition to the carrier 10 and the abrasive elements 12, the pad conditioner 1 comprises a spacer 14. The spacer 14 is disposed on the surface 101 of the carrier 10 and covers at least a portion of the exposed region 103. The spacer 14 includes a first surface 141 and a second surface 143 opposed to each other, and the second surface 143 of the spacer 14 is adjacent to the surface 101 of the carrier (as shown in FIG. 2). The second surface 143 of the spacer 14 can be fixed to the carrier 10 via an adhesive, such as 3M™ VHB™ tape or 3M™ SCOTCH-WELD™ epoxy adhesive, but not limited there to. For example, the spacer can be integrated with the carrier. The coverage ratio of the spacer 14 to the exposed region 103 of the surface 101 of the carrier 10, may range from 1.7% to 100%.

In this embodiment, the spacer 14 is a 5-lobed shape, which has plural concaves 145 at the peripheral thereof, so as to accommodate the abrasive element 12. However, the shape of the spacer 14 is not limited. As shown in FIG. 5, the spacer 24 may comprise plural openings 241, and each opening 241 is incorporated with one of the abrasive elements 12. The periphery of the spacer 24 is substantially aligned with the outer edge of the carrier 10, and thus the covering rate of the spacer 24 to the exposed region 103 of the surface 101 of the carrier 10 is about 100%.

Please refer to FIGS. 5-8, in some other embodiments, the spacer 34, 44, 54 is substantially circular shape or ring shape and disposed on the carrier concentrically within the circumference of the carrier 10. As shown in FIG. 6, the spacer 34 is about the same size as the abrasive elements 12 and being disposed at the center of the carrier 10. In other words the center of spacer 34 aligns with the center of the carrier 10. In this embodiment, the diameter of the carrier 10 is about 107.95 mm and the diameter of the abrasive element 12 is about 13.6 mm, therefore, the coverage ratio of the spacer 34 to the exposed region 103 of the carrier 10 is approximately 1.7%.

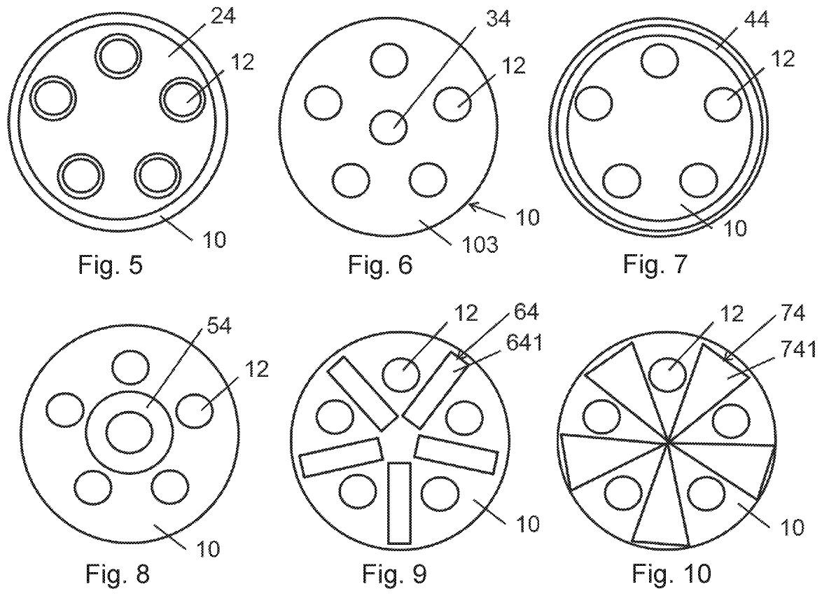

In some other embodiments, the spacer can be a ring shape. Please refer to FIG. 7, the spacer 44 is a circular ring shape and being disposed on the carrier 10 concentrically within the circumference of the carrier 10. The abrasive elements 12 are disposed within the inner edge of the spacer 44, and the outer edge of the spacer is within the circumference of the carrier 10. But the size of the ring is not limited, for example, as shown in FIG. 8, the circular ring shaped spacer 54 is smaller than that of FIG. 7, wherein the diameter of the outer edge of the spacer 54 is less than the diameter of the circle where the abrasive elements are arranged.

In yet some other embodiments, the spacer 64, 74 includes a plurality of ribs 641, 741. As shown in FIGS. 9 and 10, the spacer 64 comprises plural ribs 641, and each of the rib 641, 741 is spaced in an equal interval around the circumference of the carrier 10, and one abrasive element 12 is disposed between the adjacent two ribs 641. In other words, the ribs 641 are arranged as radial shape. The shape of the rib is not limited, for example, which can be rectangular shape (as shown in FIG. 9) or triangle (as shown in FIG. 10). Also, the ribs 641 can be separated from each other (as shown in FIG. 9) or in contact with each other (as shown in FIG. 10).

According to these embodiments, it is to be understood that the coverage ratio of the spacer to the exposed region of the surface of the carrier is ranged from 1.7% to 100%. For example: 1.7%, 5.0%, 10.0%, 15.0%, 20.0%, 25.0%, 30.0%, 35.0% 40.0%, 45.0%, 50.0%, 55.0%, 60.0%, 65.0%, 70.0%, 75.0%, 80.0%, 85.0%, 90.0%, 90.0%, 100.0% or any of the percentage between 1.7% to 100.0%.

Referring now to FIG. 2, the spacer 14 further comprises an inclined edge 147, and the angle A between the inclined edge 147 and the surface 101 of the carrier 10 is ranged from 10 to 80 degrees. In another embodiment, the angle A is ranged between 30 to 60 degrees. In the other embodiment, the angle A is approximately 45 degrees. The spacer 14 has a thickness, in other words, there is a distance D2 between the first surface 141 and the surface 101 of the carrier 10 when the spacer 14 is disposed on the surface 101 of the carrier 10. The distance D2 is approximately ranged from 2.9 mm to 3.5 mm. To avoid the influence of the spacer 14 on the abrasive capability of the abrasive element 12, the distance D2 between the first surface 141 of the spacer 14 and the surface 101 of carrier 10 is less than the distance D1 between the distal end 125 of the highest feature 123 on the working surface 121 of the abrasive element 12. In some embodiments, the differences between distances D1 and D2 is ranged between 0.2 mm to 0.7 mm. For example, the differences between distances D1 and D2 can be 0.2 mm, 0.3 mm, 0.4 mm, 0.5 mm, 0.6 mm, 0.7 mm, or any of the number between 0.2 mm to 0.7 mm.

The spacer 14 can be made of materials that is durable to various kind of slurry used in the CMP process and that will not interact with the slurry, the pad, or the pad conditioner itself. For example, the material of the spacer 14 can be selected from a polymer such as polyethylene (PE), polypropylene (PP), poly Styrene (PS), poly(vinyl chloride) (PVC), acrylonitrile butadine styrene (ABS), polymethylmethacrylate (PMMA), polyamide (PA), polyoxy methylene (POM), poly(butylene terephthalate) (PBT), polycarbonate (PC), poly(phenylene oxide) (PPO), polyphenylene sulfide (PPS), poly(propylene imine) (PI), liquid crystal plastic (LCP), poly (tetrafluoroethylene) (PTFE), poly(ether-ether-ketone) (PEEK), polycyclic aromatic resin (PAR), polysufone (PSF), polyethersulfone (PES), polyetherimide (PEI) or poly-(amide-imide) (PAI), phenol-formaldehyde resin, Melamine resin, urea-formaldehyde resin (UF), polyurethane (PU), or epoxy resin, but not limited thereto. In other embodiments, the material of the spacer 14 can comprise ceramic such as sapphire or glass. In other aspects of the invention, the spacer may be a brush material such as BRUSHLON products from 3M Company, USA. In general, the downward force when polishing the pad may be about 4-10 pounds, and may be as high as 15 pounds. Therefore, thus the hardness of the spacer 14 is preferably high enough to withstand these forces, to provide a support function and to avoid the unbalance of the pad conditioner if the pad conditioner sweeps beyond the pad diameter.

The pad conditioner 1 with spacer can be applied in the wafer chemical mechanical planarization (CMP) system. As shown in FIG. 4, the wafer chemical mechanical planarization system 8 comprises a platen 81, a pad 82, and a pad conditioner 1. The pad 82 is disposed on the platen 80 and includes an abrasive face 821. The pad conditioner 1 is similar to that in FIG. 1, which is not redundantly described here. In the wafer chemical mechanical planarization system 8, the surface 101 of the carrier 10 faces the abrasive face 821 of the pad 82, the surface 101 is substantially parallel to the abrasive face 821. The features 123 of the abrasive element 12 is in contact with the abrasive face 821 of the pad 82 to condition the abrasive surface 821. The distal end 125 of the highest feature 123 of the abrasive element 12 and the abrasive face 821 of the pad 82 has a gap G therebetween, in some embodiments, the gap G is greater than or equal to 0.2 mm but no greater than 0.7 mm. For example, the gap G can be 0.2 mm, 0.3 mm, 0.4 mm, 0.5 mm, 0.6 mm, 0.7 mm, or any of the number between 0.2 mm to 0.7 mm.

Please refer to FIG. 4, when the pad conditioner 1 is sweeping across the edge of the of the pad 82, for example, when one of the abrasive element 12 goes beyond the edge of the pad, the spacer 14 of the pad conditioner 1 can support the pad conditioner 1 and keep the balance of the pad conditioner 1 to mitigate the tilt of the pad conditioner 1 with respect to the pad 82. Therefore, rocking and gouging of the edge of the pad 82 cased due to the oscillation can be moderated. In addition, when the pad conditioner 1 sweeps back to the center of the pad 82, the inclined edge 147 of the spacer 14 can prevent the pad 82 edge damage. Pad conditioners of the present invention are also able to condition the edges of the pad so that the CMP performance (e.g., material removal rate) is uniform across the wafer surface.

The present invention is further described with the following examples:

### EXAMPLES

### Comparative Example 1

A TRIZACT B25-2910-5S2 disk (from 3M Company, St. Paul, Minn., US) was placed on an AMAT REFLEXION tool (from Applied Materials, Inc., Santa Clara, Calif., US). This disk had no spacer. The pad was a JSR CMP 9006-FPJ pad (from JSR Corporation, Tokyo, JP). The disk was positioned near the edge of the pad (outer radial sweep position) (step 1), and then the disk was lowered until it was in contact at 6 lbs down force (step 2). A photograph of the disk was taken to document the tilt (step 3). Raised the disk off the pad and increment the disk position outwards to document the tilt (Step 4). Steps 3 and 4 were repeated to document the tilt.

### Example 1

The disk, tool and pad were the same as those in comparative Example 1, except that a spacer of the present invention was attached to the disk via VHB tape (from 3M Company, St. Paul, Minn. US). The spacer was a 5-lobed shaped spacer made of PMMA. The thickness of the spacer was 3 mm, and the chord length of each arc was 47.2 mm. Steps 3 and 4 as described above for Comparative Example 1 were repeated to record the tilt.

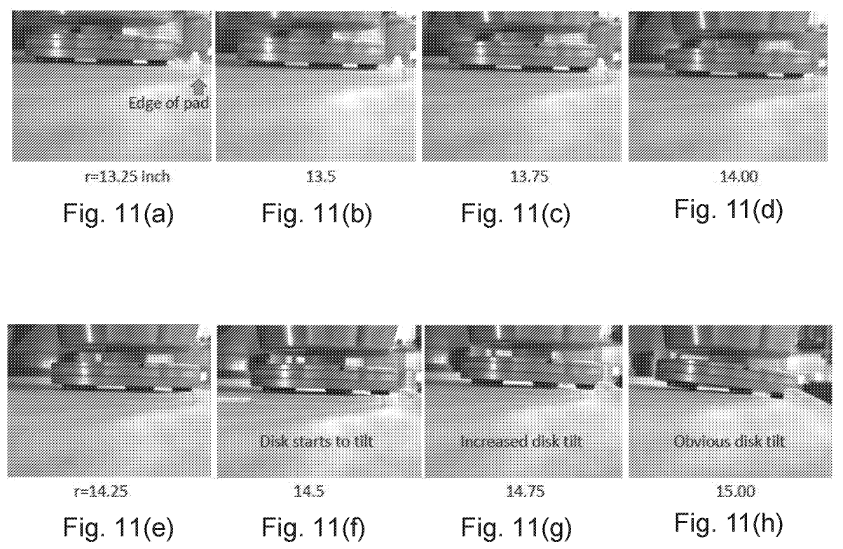

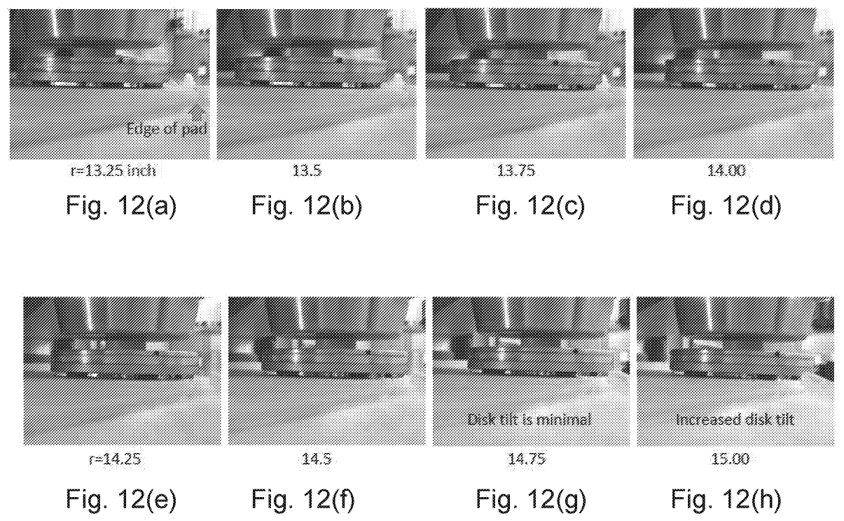

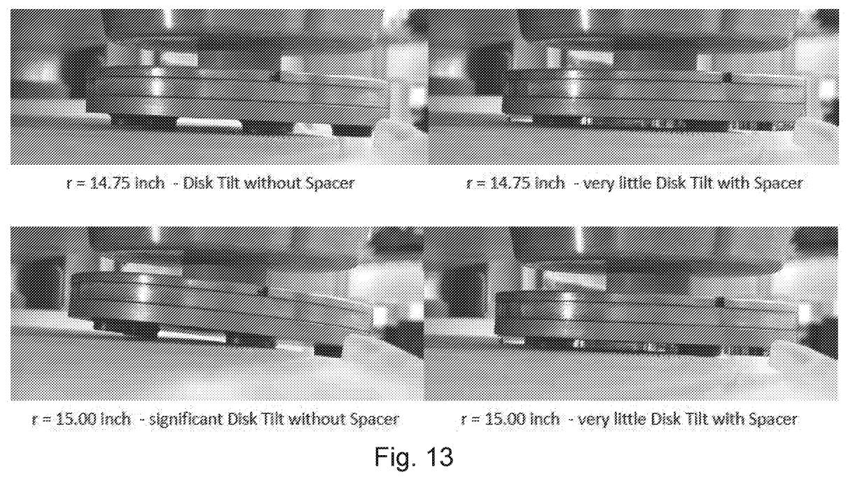

Results are shown in FIGS. 11-13. When the disk extended to a point where at least one element was not supported by the pad, some tilt was evident in the Comparative Example with no spacer (FIG. 11(f)-(h)). With the spacer, the amount of tilt is substantially reduced (FIGS. 12 and 13).

Although the invention has been described in detail with reference to certain embodiments thereof, other versions are possible. Therefore the spirit and scope of the appended claims should not be limited to the description and the drawings in this specification. It is to be understood that the terminology used in the description is for the purpose of describing the particular versions or embodiments only, and is not intended to limit the scope of the present invention.

1. A pad conditioner, comprising:
a carrier comprising a surface with an exposed region and a plurality of mounting regions;
at least one abrasive element disposed on the mounting region of the surface of the carrier, the at least one abrasive element having a working surface which includes a plurality of features each having a distal end; and
a spacer disposed on the surface of the carrier and covering at least a portion of the exposed region, wherein the spacer has a first surface and a second surface opposed to the first surface, the second surface adjacent to the surface of the carrier;
wherein the—distance (D1) between the distal end of the highest feature of the at least one abrasive element and the surface of the carrier is greater than the distance (D2) between the first surface of the spacer and the surface of the carrier.

2. The pad conditioner according to claim 1, wherein the at least one abrasive element comprises one or more of: superabrasive grit in a metal matrix, ceramic bodies comprising ceramic material in an amount of at least 85% by weight, and ceramic bodies comprising a diamond coating.

3. The pad conditioner according to claim 1, wherein the plurality of features of the abrasive element is precisely shaped features.

4. The pad conditioner according to claim 1, wherein the abrasive elements are spaced apart in an equal interval around the circumference of the carrier.

5. (canceled)

6. (canceled)

7. The pad conditioner according to claim 5, wherein the spacer is disposed concentrically within the circumference of the carrier.

8. The pad conditioner according to claim 5, wherein the spacer further comprises a plurality of ribs, and each of the rib is spaced in an equal interval around the circumference of the carrier.

9. The pad conditioner according to claim 1, wherein the spacer further comprises an inclined edge, and the angle (A) between the inclined edge and the surface of the carrier is from 10 degrees to 80 degrees.

10. (canceled)

11. (canceled)

12. The pad conditioner according to claim 1, wherein the differences between D1 and D2 is no less than 0.2 mm.

13. (canceled)

14. (canceled)

15. A spacer for a pad conditioner, the pad conditioner comprising a carrier having a surface with a plurality of mounting regions and an exposed region, and at least an abrasive element disposed on the mounting region and having a plurality of features each having a distal end, the spacer comprising a first surface and a second surface opposed to the first surface and adjacent to the carrier, wherein the distance (D1) between the distal end of the highest feature of the abrasive element and the surface of the carrier is greater than the distance (D2) between the first surface of the spacer and the surface of the carrier.

16. (canceled)

17. The spacer according to claim 15, wherein the spacer further comprising an inclined edge, and the angle (A) between the inclined edge and the surface of the carrier is from 10 degrees to 80 degrees.

18. The spacer according to claim 15, wherein the differences between D1 and D2 is no less than 0.2 mm.

19. (canceled)

20. A wafer chemical mechanical planarization system, comprising:
a platen;
a pad disposed on the platen and having an abrasive face; and
a pad conditioner comprising:
a carrier comprising a surface with an exposed region and a plurality of mounting regions;
at least one abrasive element disposed on the mounting region of the surface of the carrier, the at least one abrasive element having a working surface facing the pad and including a plurality of features each having a distal end; and
a spacer disposed on the surface of the carrier and covering at least a portion of the exposed region, wherein the spacer has a first surface and a second surface opposed to the first surface, the second surface adjacent to the surface of the carrier;
wherein the distal end of the highest feature of the abrasive element is in contact with the abrasive face of the pad, and the first surface of the spacer and the abrasive face of the pad have a gap (G) therebetween.

21. The wafer chemical mechanical planarization system according to claim 20, wherein the plurality of features of the abrasive element is precisely shaped features.

22. The wafer chemical mechanical planarization system according to claim 20, wherein the abrasive elements of the pad conditioner are spaced apart in an equal interval around the circumference of the carrier.

23. The wafer chemical mechanical planarization system according to claim 22, wherein the spacer of the pad conditioner is disposed concentrically within the circumference of the carrier.

24. The wafer chemical mechanical planarization system according to claim 22, wherein the spacer of the pad conditioner further comprises a plurality of ribs, and each of the rib is spaced in an equal interval around the circumference of the carrier.

25. (canceled)

26. The wafer chemical mechanical planarization system according to claim 20, wherein the spacer of the pad conditioner further comprises an inclined edge, and the angle (A) between the inclined edge and the surface of the carrier is from 10 degrees to 80 degrees.

27. The wafer chemical mechanical planarization system according to claim 20, wherein the gap (G) is no less than 0.2 mm.

28. (canceled)

29. (canceled)
